(19) United States
(12) Patent Application Publication
(10) Pub. No.: US 2022/0338363 A1
(43) Pub. Date: Oct. 20, 2022

(54) HOUSINGS OF COMPUTING DEVICES

(71) Applicant: Hewlett-Packard Development Company, L.P., Spring, TX (US)

(72) Inventors: Wen Chih Chen, Taipei City (TW); Po Feng Chuang, Taipei City (TW); Xiao Jun Zhu, Chongqing (CN); Li Jia, Chongqing (CN)

(21) Appl. No.: 17/231,372

(22) Filed: Apr. 15, 2021

(51) Int. Cl. H05K 5/06

(52) U.S. Cl. CPC H05K 5/061; H05K 5/069

(57) ABSTRACT

In some examples, a computing device can include a housing including a corner, the corner comprising a first surface and a second surface, and an inner frame including a chamfered corner to interface with the corner of the housing to form a cavity between the first surface, the second surface, and the chamfered corner, a first gasket to interface with the first surface of the housing, and a second gasket to interface with the second surface of the housing, where the cavity includes a structural adhesive and the first gasket and the second gasket fluidically seal the cavity.

### BACKGROUND

Computing devices can allow a user to utilize computing device operations for work, education, gaming, multimedia, and/or other uses. Computing devices can be portable to allow a user to carry or otherwise bring the computing device with while in a mobile setting. A computing device can allow a user to utilize computing device operations for work, education, gaming, multimedia, and/or other general use in a mobile setting.

### BRIEF DESCRIPTION OF THE DRAWINGS

FIG. 1 is a sectioned perspective view of an example of a computing device housing and inner frame consistent with the disclosure.

FIG. 2 is a partial perspective view of an example of a housing consistent with the disclosure.

FIG. 3 is a partial perspective view of an example of an inner frame consistent with the disclosure.

FIG. 4 is a perspective view of an example of a computing device having a housing and inner frame consistent with the disclosure.

FIG. 5 is a sectioned perspective view of an example of a computing device having a housing and an inner frame having a first gasket and a second gasket consistent with the disclosure.

FIG. 6 illustrates a method of manufacture for a computing device having a housing and inner frame consistent with the disclosure.

FIG. 7 is a flowchart for a method of manufacture for a computing device housing and inner frame consistent with the disclosure.

### DETAILED DESCRIPTION

A user may utilize a computing device for various purposes, such as for business and/or recreational use. As used herein, the term “computing device” refers to an electronic system having a processor resource and a memory resource. Examples of computing devices can include, for instance, a laptop computer, a notebook computer, an all-in-one (AIO) computer, among other types of computing devices.

When a computing device is utilized in a mobile setting, a user may transport the computing device from place to place. A user may transport the computing device by carrying the computing device. For instance, the user may pick up the computing device from a desk and carry the computing device to a table in a different location.

When utilizing the computing device in a mobile setting, there can be a possibility that the computing device is dropped. Dropping the computing device can cause damage to the computing device. For example, a computing device dropped on a particularly weak portion of the computing device may result in damage to a housing of the computing device, the inner components of the computing device, etc. Such damage may be visually and/or aesthetically displeasing. However, in some examples, such damage may further extend to computing components of the computing device, which may result in the computing device not functioning properly.

In previous approaches the housing may be tooled out of a metal material (e.g., aluminum) and tooling approaches, which may be selected based on cost constraints, may result in loose tolerances. The inner frame may have to have a chamfer cut in order to avoid interference when assembling the inner frame and the housing. However, such tooling tolerances and the chamfer can result in a space between the inner frame and the housing, which can be a weak portion subject to damage if the computing device is dropped.

Housings of computing devices according to the disclosure can allow for a housing of a computing device to be interfaced with an inner frame in a manner that structurally seals a cavity located between the housing and the inner frame. Such structural protection can prevent damage to the portion of the computing device with the structurally sealed cavity if the computing device is dropped and contacts a surface at the location of the housing having the structurally sealed cavity and can provide additional rigidity to the housing of the computing device as compared with previous approaches.

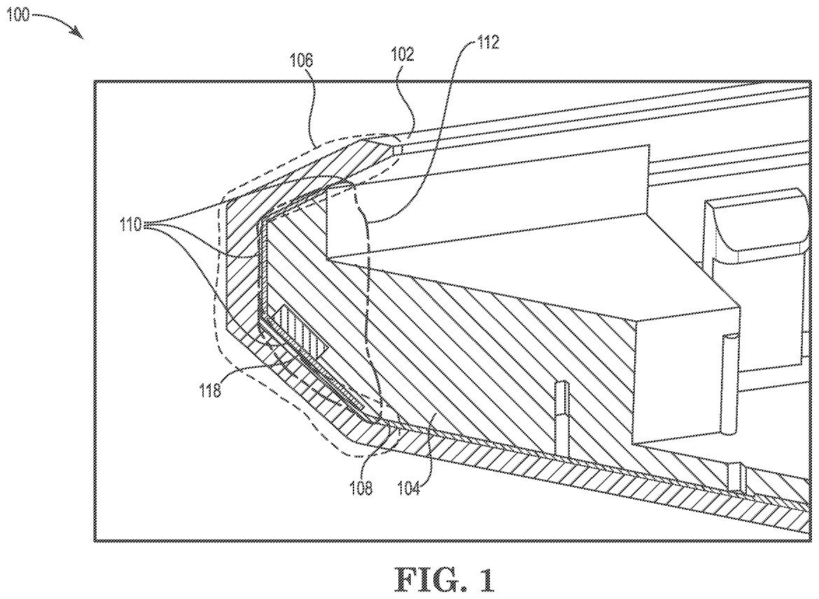

FIG. 1 is a sectioned perspective view of an example of a computing device 100 having a housing 102 and inner frame 104 consistent with the disclosure. As illustrated in FIG. 1, the housing 102 can include a corner 106 having a first surface 108 and a second surface 110. The inner frame 104 can include a chamfered corner 112 and a second gasket 118.

The computing device 100 can include the housing 102. As used herein, the term “housing” refers to an outer shell of a device. For example, the housing 102 can be an outer shell that includes other components. Such components can be, for example, the inner frame 104 as is further described herein.

The housing 102 can be constructed of an aluminum material. Such aluminum material for the housing 102 can include aluminum sheet metal, aluminum billet formed or cut by computer numerical controlled (CNC) machines, etc. The aluminum of the housing 102 can be tooled to provide such a housing 102 for use in the computing device 100.

Although the housing 102 is described above as being an aluminum material, examples of the disclosure are not so limited. For example, the housing 102 can be of any other metal material (e.g., magnesium), can be of a plastic material such as a plastic injected material having an undercut, etc.

The housing 102 can include a corner 106. As used herein, the term “corner” refers to a place at which converging surfaces meet. For example, the corner 106 can be a location on the housing 102 at which the first surface 108 and the second surface 110 come together and meet.

During such tooling of the housing 102, inner dimensions of the corner 106 may not be easily controlled. For example, dimensions of the corner 106 as modeled may not be fully realized as a result of tooling constraints during manufacturing of the housing 102. As a result, in previous approaches when the inner frame 104 was interfaced with the housing 102, a cavity would result. In previous approaches, such a cavity could allow for structural damage to the housing of the computing device and/or damage to computing components of the computing device when the computing device was dropped. Accordingly, housings of computing devices according to the disclosure can allow for the cavity to be structurally sealed as is further described herein.

As mentioned above, the housing 102 can include a first surface 108. The first surface 108 can be, for instance, a side surface of the housing 102. The first surface 108 can include apertures for electrical connections for various input/output (I/O) and/or other peripheral devices for the computing device 100.

The housing 102 can include a second surface 110. The second surface 110 can have a stepped curvature. For example, the second surface 110 can be shaped in a manner of a bending line formed by a repeated pattern of obtuse angled surfaces. However, examples of the disclosure are not so limited. For example, the second surface 110 can be a flat surface similar to first surface 108, a rounded surface, or have another profile or shape.

The computing device 100 can include an inner frame 104. As used herein, the term “inner frame” refers to a rigid structure to support other objects. For example, the inner frame 104 can be a rigid structure located inside the housing 102 of the computing device 100. The inner frame 104 can support hardware components of the computing device 100. For instance, the inner frame 104 may support components such as a motherboard, power supply, drives (e.g., floppy drives or optical drives such as CD-ROM, CD-RW, DVD-ROM, etc.), hard disk, video card, sound card, peripheral devices (e.g., keyboard, touchpad, mouse, etc.), among other components of the computing device 100.

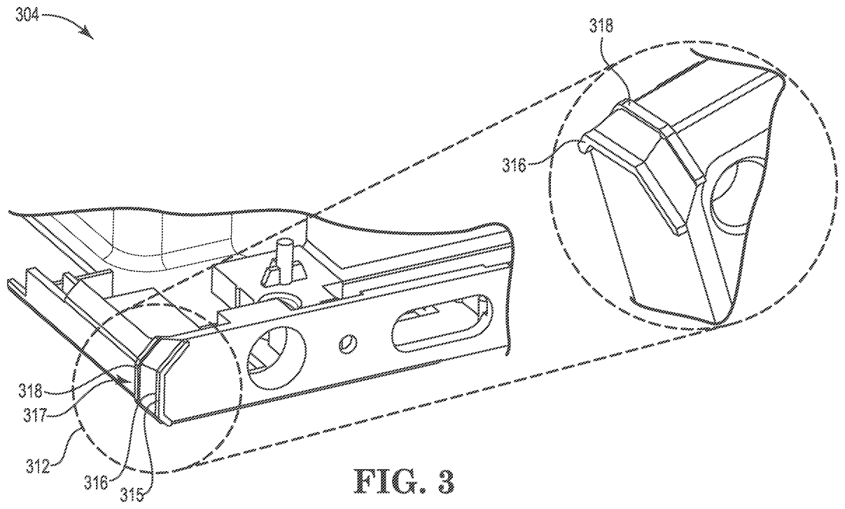

The inner frame 104 can include a chamfered corner 112. The chamfered corner 112 can include a first gasket (e.g., not illustrated in FIG. 1) and a second gasket 118, as is further described in connection with FIG. 3.

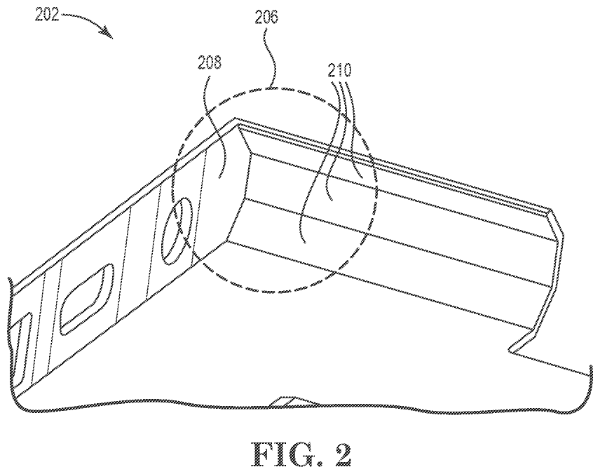

FIG. 2 is a partial perspective view of an example of a housing 202 consistent with the disclosure. The housing 202 can include a corner 206.

The corner 206 can include a first surface 208 and a second surface 210. As previously described in connection with FIG. 1, the second surface 210 can include a stepped curvature. The stepped curvature of the second surface 210 may be a structural component of the housing 202, may be an aesthetically pleasing surface, etc. The corner 206 can be the location on the housing 202 where the first surface 208 and the second surface 210 meet.

FIG. 3 is a partial perspective view of an example of an inner frame 304 consistent with the disclosure. The inner frame 304 can include a chamfered corner 312.

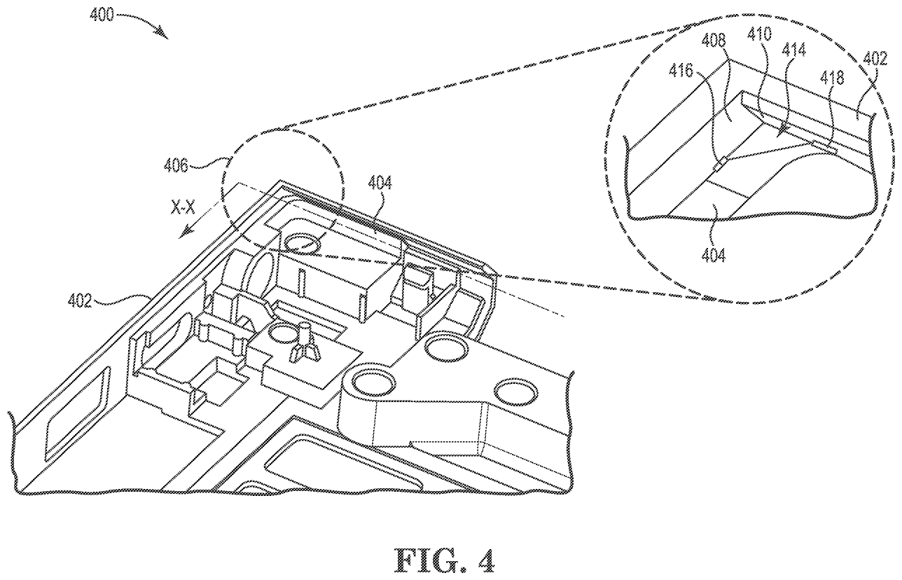

As used herein, the term “chamfered corner” refers to a transitional edge between surfaces of an object. For example, the chamfered corner 312 can be a transitional surface where the inner frame 304 is intended to interface with a corner (e.g., corner 106, 206, previously described in connection with FIGS. 1 and 2, respectively) of the housing (e.g., housing 102, 202, previously described in connection with FIGS. 1 and 2, respectively) of the computing device. The chamfered corner 312 can form a cavity between a first surface of the housing, a second surface of the housing, and the chamfered corner 312 of the inner frame 304, as is further described in connection with FIGS. 4-6.

The chamfered corner 312 can include a first perimeter surface 315. As used herein, the term “perimeter surface” refers to an external border between surfaces. The first perimeter surface 315 can include a stepped curvature so as to be able to interface with the stepped curvature of the second surface of the housing. The first perimeter surface 315 can be a surface on which a first gasket 316 is located. That is, the first gasket 316 can be located on the first perimeter surface 315 of the chamfered corner 312. As a result, the first gasket 316 can be positioned to have a stepped curvature corresponding to that of the first perimeter surface 315. As used herein, the term “gasket” refers to a device to place around a joint to make it impervious to the transition of fluid through or around the device.

The chamfered corner 312 can include a second perimeter surface 317. The second perimeter surface 317 can also include a stepped curvature so as to be able to interface with the stepped curvature of the second surface of the housing. The second perimeter surface 317 can be a surface on which a second gasket 318 is located. That is, the second gasket 318 can be located on the second perimeter surface 317 of the chamfered corner 312. As a result, the second gasket 318 can be positioned to have a stepped curvature corresponding to that of the second perimeter surface 317.

The first gasket 316 and the second gasket 318 can fluidically seal the cavity formed between a first surface of the housing, a second surface of the housing, and the chamfered corner 312. That is, the first gasket 316 and the second gasket 318 can prevent a structural adhesive from transitioning outside of the cavity (e.g., prevent the structural adhesive from transitioning through or around the first gasket 316 and the second gasket 318), as is further described in connection with FIGS. 4-6.

The first gasket 316 and the second gasket 318 can be of a liquid silicone rubber material. The liquid silicone rubber material can be an elastomer material that can function as a gasket, as described above.

While the first gasket 316 and the second gasket 318 are described above as being of a liquid silicone rubber material, examples of the disclosure are not so limited. For example, the first gasket 316 and the second gasket 318 can be, for example, a rubber elastomer, urethane, silicone, and/or any other polymer or elastomer material that can fluidically seal the cavity formed between a first surface of the housing, a second surface of the housing, and the chamfered corner 312. Additionally, the first gasket 316 and the second gasket 318 can be of different materials.

FIG. 4 is a perspective view of an example of a computing device 400 having a housing 402 and inner frame 404 consistent with the disclosure. The housing 402 can include a corner 406.

As illustrated in FIG. 4, the inner frame 404 is interfaced with the housing 402. As used herein, the term “interface” refers to two objects being in physical contact with each other at a common boundary. For example, when the inner frame 404 is interfaced with the housing 402, a portion of the inner frame 404 can be in physical contact with a portion of the housing 402. When the inner frame 404 is interfaced with the housing 402, a cavity 414 can be formed as a result of manufacturing tolerances of the housing 402 and the chamfered corner of the inner frame 404. As used herein, the term “cavity” refers to a hollow space within an object or series of objects. For example, the cavity 414 can be a hollow space formed between the first surface 408 of the housing 402, the second surface 410 of the housing 402, and the chamfered corner of the inner frame 404.

When the inner frame 404 is interfaced with the housing 402, the first gasket 416 can interface with the first surface 408. For example, the first gasket 416 can be compressed against the first surface 408 of the housing 402 when the inner frame 404 is interfaced with the housing 402. Additionally, although the first gasket 416 is located on the perimeter surface of the inner frame 404 in such a way so as to have a stepped curvature corresponding to that of the first perimeter surface (e.g., as previously described in connection with FIG. 3), the first gasket 416 interfaces with the flat first surface 408.

Additionally, when the inner frame 404 is interfaced with the housing 402, the second gasket 418 can interface with the second surface 410. For example, the second gasket 418 can be compressed against the second surface 410 of the housing 402 when the inner frame 404 is interfaced with the housing 402. The stepped curvature of the second perimeter surface (e.g., as previously described in connection with FIG. 3), and as a result the stepped curvature of the second gasket 418, can allow the second gasket 418 to interface with each “stepped” portion of the second surface 410 for the entirety of the stepped curvature of the second surface 410.

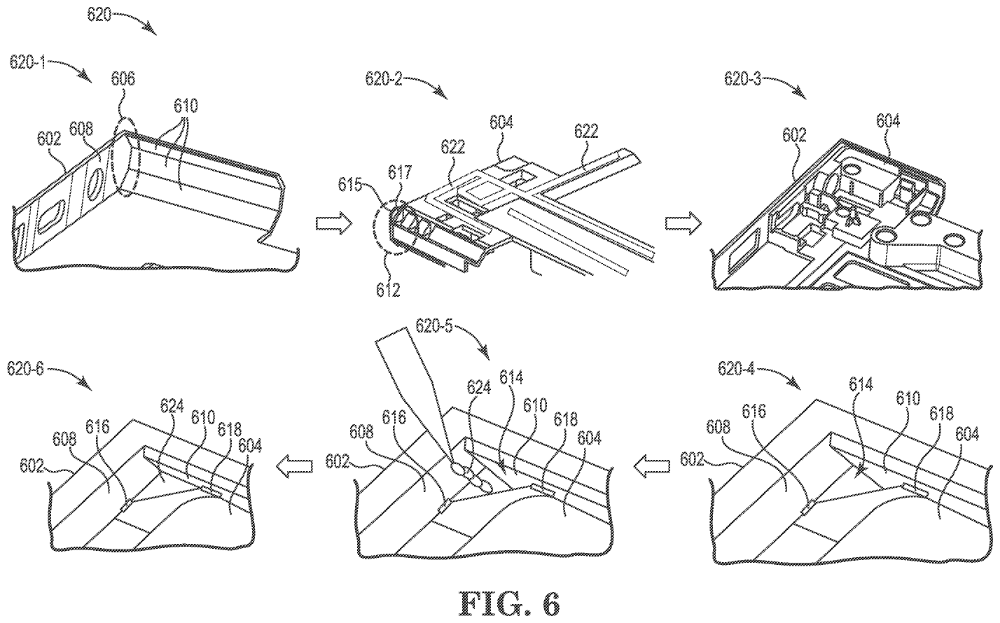

The first gasket 416 and the second gasket 418 can fluidically seal the cavity 414. For example, a structural adhesive can be added to the cavity 414, and the first gasket 416 and the second gasket 418 can keep the structural adhesive within the cavity 414, as is further described in connection with FIG. 6.

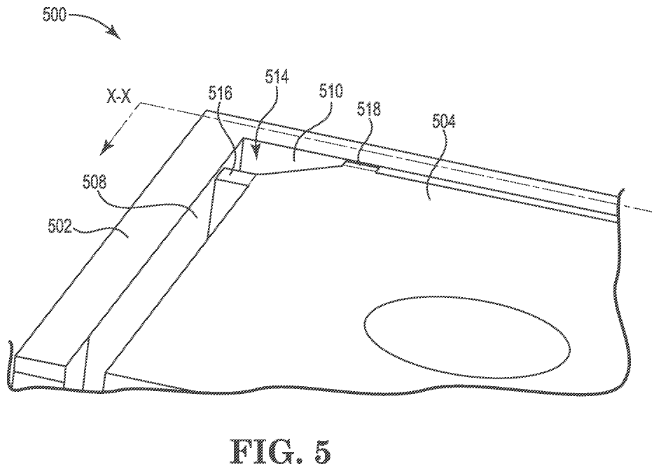

As illustrated in FIG. 4, section X-X is shown as being located halfway down the second surface 410. Such a section view is further illustrated and described in connection with FIG. 5.

FIG. 5 is a sectioned perspective view of an example of a computing device 500 having a housing 502 and an inner frame 504 having a first gasket 516 and a second gasket 518 consistent with the disclosure. The inner frame 504 can be interfaced with the housing 502.

In the section view illustrated in FIG. 5 and indicated by section X-X, the second surface 510 is shown at the middle portion of the stepped curvature of the second surface 510. The second gasket 518 can be compressed against the second surface 510 of the housing 502 through the stepped curvature of the second surface 510.

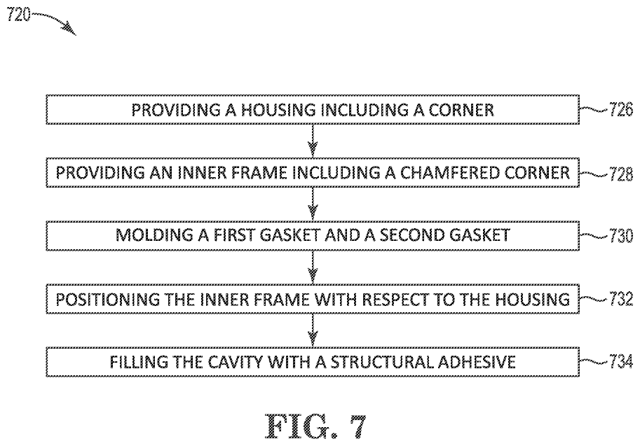

Additionally, the first gasket 516 can be compressed against the first surface 508 of the housing 502. The first gasket 516 and the second gasket 518 can fluidically seal the cavity 514 when a structural adhesive fills the cavity 514, as is further described in connection with FIGS. 6 and 7.

FIG. 6 illustrates a method of manufacture 620 for a computing device having a housing 602 and inner frame 604 consistent with the disclosure. At 620-1, the method 620 can include providing a housing 602 including a corner 606. The corner 606 can comprise a first surface 608 and a second surface 610. As illustrated in FIG. 6, the second surface 610 can include a stepped curvature. The housing 602 can be provided from aluminum sheet metal, although examples of the disclosure are not limited to aluminum sheet metal, as the housing 602 can be provided from plastic and/or any other type of material.

At 620-2, the method 620 includes providing an inner frame 604. The inner frame 604 can include a chamfered corner 612. The chamfered corner 612 can include a first perimeter surface 615 and a second perimeter surface 617. Providing the inner frame 604 can include molding the inner frame 604 by insert molding. However, examples of the disclosure are not limited to insert molding. For example, the inner frame 604 can be provided by injection molding, overmolding, three-dimensional (3D) printing, etc.

The method 620 can include molding a first gasket to the first perimeter surface 615 and a second gasket to the second perimeter surface 617. For example, the first gasket (e.g., first gasket 616) can be insert molded to the first perimeter surface 615 and the second gasket (e.g., second gasket 618) can be insert molded to the second perimeter surface 617.

At 620-2, a thermal adhesive 622 can be added to the inner frame 604. As used herein, the term “thermal adhesive” refers to a thermally conductive substance that causes adhesion between objects. As illustrated in FIG. 6, the thermal adhesive 622 can be added to a “bottom” surface of the inner frame 604. Such a “bottom” surface can interface with a “bottom surface” of the housing 602 and the thermal adhesive 622 can cause adhesion between the inner frame 604 and the housing 602 when the inner frame 604 is positioned with respect to the housing 602 as is further described herein.

At 620-3, the method 620 can include positioning the inner frame 604 with respect to the housing 602. Positioning the inner frame 604 with respect to the housing 602 can include attaching the inner frame 604 to the housing 602 by the thermal adhesive 622.

When the inner frame 604 is positioned with respect to the housing 602, the chamfered corner 612 can interface with the corner 606. At 620-4, the first gasket 616 can compress against the first surface 608 of the housing 602 and the second gasket 618 can compress against the second surface 610 of the housing 602. As shown at 620-4, the top portion of the stepped curvature of the second surface 610 is shown when the inner frame 604 is positioned with respect to the housing 602. In such a positioning, the first surface 608, the second surface 610, and the chamfered corner (e.g., chamfered corner 612 shown at 620-2) can create the fluidically sealed cavity 614.

At 620-5, the method 620 can include filing the cavity 614 with structural adhesive 624. As used herein, the term “structural adhesive” refers to a substance that causes adhesion and structural integrity between two objects. For example, the structural adhesive 624 can provide support and rigidity to the cavity 614. Accordingly, if the computing device is dropped and the computing device contacts another surface at the location of the corner 606, the structural adhesive 624 can provide support and rigidity to help absorb the impact to help to prevent the housing 602 and/or the inner frame 604 from cracking.

Filling the cavity 614 with structural adhesive 624 can include injecting the structural adhesive 624 into the cavity 614. When the structural adhesive 624 is being provided to the cavity 614, the first gasket 616 and the second gasket 618 can prevent the structural adhesive 624 from exiting the cavity 614. That is, the first gasket 616 and the second gasket 618 can prevent the structural adhesive 624 from transitioning through and/or around the first gasket 616 and/or the second gasket 618.

At 620-6, the method 620 can include thermally bonding the structural adhesive 624 in the fluidically sealed cavity 614. For example, a heat source can be applied to the structural adhesive 624 to bond the structural adhesive 624 in the fluidically sealed cavity 614 to the first surface 608, the second surface 610, the chamfered corner (e.g., chamfered corner 612), the first gasket 616, and the second gasket 618.

Housings of computing devices according to the disclosure can provide a housing and an inner frame having structural support in locations where tooling of the housing may cause the housing and inner frame to not interface together correctly. For example, cavities between the housing and the inner frame can be filled with a structural adhesive to structurally seal such cavities. Such structural protection can prevent damage to the portion of the computing device with the structurally sealed cavity if the computing device is dropped and contacts a surface at the location of the housing with the structurally sealed cavity and can provide additional rigidity to the housing of the computing device as compared with previous approaches

FIG. 7 is a flowchart for a method of manufacture 720 for a computing device housing and inner frame consistent with the disclosure. At 726, the method 720 can include providing a housing including a corner. The corner can comprise a first surface and a second surface. The second surface can include a stepped curvature. The housing may be provided as an aluminum housing, plastic housing, and/or housing of any other type of material. The housing may be machined, stamped, tooled, 3D printed, etc.

At 728, the method 720 can include providing an inner frame including a chamfered corner. The chamfered corner can include a first perimeter surface and a second perimeter surface. The inner frame may be provided by insert molding plastic.

At 730, the method 720 can include molding a first gasket and a second gasket. For example, a first gasket can be molded to the first perimeter surface and a second gasket can be molded to a second perimeter surface. Molding the first gasket to the first perimeter surface and the second gasket to the second perimeter surface can be done by insert molding techniques.

At 732, the method 720 can include positioning the inner frame with respect to the housing. The inner frame can be positioned with respect to the housing such that the chamfered corner of the inner frame can interface with the corner of the housing. Such positioning can cause the first gasket to compress against the first surface of the housing and the second gasket to compress against the second surface of the housing (e.g., the surface having the stepped curvature). Such positioning can further cause a fluidically sealed cavity to be formed between the first surface, the second surface, and the chamfered corner.

At 734, the method 720 can include filling the cavity with a structural adhesive. For example, the fluidically sealed cavity can receive a structural adhesive and the first gasket and the second gasket can prevent the structural adhesive from transitioning through and/or around the first gasket and/or the second gasket. The structural adhesive can then be thermally bonded.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the disclosure. Further, as used herein, “a” can refer to one such thing or more than one such thing.

The figures herein follow a numbering convention in which the first digit corresponds to the drawing figure number and the remaining digits identify an element or component in the drawing. For example, reference numeral 102 may refer to element 102 in FIG. 1 and an analogous element may be identified by reference numeral 202 in FIG. 2. Such analogous elements may be similar in structure and/or function to similarly-named elements described above. Elements shown in the various figures herein can be added, exchanged, and/or eliminated to provide additional examples of the disclosure. In addition, the proportion and the relative scale of the elements provided in the figures are intended to illustrate the examples of the disclosure, and should not be taken in a limiting sense.

It can be understood that when an element is referred to as being “on,” “connected to”, “coupled to”, or “coupled with” another element, it can be directly on, connected, or coupled with the other element or intervening elements may be present. In contrast, when an object is “directly coupled to” or “directly coupled with” another element it is understood that are no intervening elements (adhesives, screws, other elements) etc.

The above specification, examples and data provide a description of the method and applications, and use of the system and method of the disclosure. Since many examples can be made without departing from the spirit and scope of the system and method of the disclosure, this specification merely sets forth some of the many possible example configurations and implementations.

What is claimed is:

1. A computing device, comprising:
a housing including a corner, the corner comprising a first surface and a second surface; and
an inner frame including:
a chamfered corner to interface with the corner of the housing to form a cavity between the first surface, the second surface, and the chamfered corner;
a first gasket to interface with the first surface of the housing; and
a second gasket to interface with the second surface of the housing;
wherein:
the cavity includes a structural adhesive; and
the first gasket and the second gasket fluidically seal the cavity.

2. The computing device of claim 1, wherein the first gasket is compressed against the first surface of the housing.

3. The computing device of claim 1, wherein the second gasket is compressed against the second surface of the housing.

4. The computing device of claim 1, wherein the second surface includes a stepped curvature.

5. The computing device of claim 1, wherein the structural adhesive fills the cavity.

6. The computing device of claim 1, wherein the first gasket and the second gasket are a liquid silicone rubber material.

7. A system, comprising:
a housing of a computing device, the housing including a corner, wherein the corner comprises a first surface and a second surface having a stepped curvature; and
an inner frame including:
a chamfered corner to interface with the corner of the housing to form a cavity between the first surface, the second surface, and the chamfered corner;
a first gasket to interface with the first surface of the housing; and
a second gasket to interface with the second surface of the housing;
wherein:
the first gasket and the second gasket fluidically seal the cavity; and
the cavity is filled by a structural adhesive.

8. The system of claim 7, wherein the chamfered corner includes a first perimeter surface and a second perimeter surface.

9. The system of claim 8, wherein the first gasket is located on the first perimeter surface of the chamfered corner.

10. The system of claim 8, wherein the second gasket is located on the second perimeter surface of the chamfered corner.

11. A method of manufacture of a computing device, comprising:
providing a housing including a corner, wherein the corner comprises a first surface and a second surface having a stepped curvature;
providing an inner frame including a chamfered corner having a first perimeter surface and a second perimeter surface;
molding a first gasket to the first perimeter surface and a second gasket to the second perimeter surface;
positioning the inner frame with respect to the housing such that:
the chamfered corner is to interface with the corner to compress the first gasket against the first surface of the housing and compress the second gasket against the second surface of the housing; and
a fluidically sealed cavity is formed between the first surface, the second surface, and the chamfered corner via the first gasket and the second gasket; and
filling the cavity with a structural adhesive.

12. The method of claim 11, including molding the first gasket to the first perimeter surface and the second gasket to the second perimeter surface by insert molding.

13. The method of claim 11, including providing the inner frame by insert molding the inner frame.

14. The method of claim 11, wherein positioning the inner frame with respect to the housing includes attaching the inner frame to the housing by a thermal adhesive.

15. The method of claim 11, including thermally bonding the structural adhesive in the fluidically sealed cavity to the first surface, the second surface, the chamfered corner, the first gasket, and the second gasket.
